(19) United States
(12) Patent Application Publication
(10) Pub. No.: US 2025/0301569 A1
(43) Pub. Date: Sep. 25, 2025

(54) STRETCHABLE DEVICE

(71) Applicant: Murata Manufacturing Co., Ltd., Nagaokakyo-shi (JP)

(72) Inventors: Toshifumi ASUKAI, Nagaokakyo-shi (JP); Hayato KATSU, Nagaokakyo-shi (JP); Takayoshi OBATA, Nagaokakyo-shi (JP)

(21) Appl. No.: 19/227,713

(22) Filed: Jun. 4, 2025

Related U.S. Application Data
(63) Continuation of application No. PCT/JP2024/019490, filed on May 28, 2024.

(30) Foreign Application Priority Data
Jun. 6, 2023 (JP) 2023-093163

(51) Int. Cl. H05K 1/02

(52) U.S. Cl. CPC H05K 1/0283

(57) ABSTRACT

A stretchable device that includes: a stretchable substrate; and a stretchable wiring on the stretchable substrate, in which a loss elastic modulus E″ (S) of the stretchable substrate is smaller than a loss elastic modulus E″ (W) of the stretchable wiring.

### CROSS REFERENCE TO RELATED APPLICATIONS

The present application is a continuation of International application No. PCT/JP2024/019490, filed May 28, 2024, which claims priority to Japanese Patent Application No. 2023-093163, filed Jun. 6, 2023, the entire contents of each of which are incorporated herein by reference.

### TECHNICAL FIELD

The present disclosure relates to a stretchable device.

### BACKGROUND ART

Conventionally, a stretchable device including a stretchable substrate and a stretchable wiring disposed on the stretchable substrate has been known.
Patent Document 1: Japanese Patent Application Laid-Open No. 2020-181958

### SUMMARY OF THE DISCLOSURE

Here, the inventors of the present application have found that there are matters to be improved in the stretchable device in the following points.

Specifically, in the stretchable device, a proportion of the stretchable substrate to the stretchable wiring is relatively large, and thus, this may increase a degree of contribution to a stretching behavior as the entire device. Hence, in the case of a stretchable substrate easily plastically deforming (that is, easily relaxing) in stretching, this causes the stretchable wiring disposed on the stretchable substrate to gradually extend, which raises a fear that a wiring resistance of the stretchable wiring becomes high.

From the above, it is desirable that when the stretchable device is stretched, the stretchable substrate, which is a constituent element of the stretchable device, be less likely to plastically deform.

Therefore, an object of the present disclosure is to provide a stretchable device including a stretchable substrate that is less likely to plastically deform when the stretchable device is stretched.

To achieve the above object, in an embodiment of the present disclosure, a stretchable device includes: a stretchable substrate; and a stretchable wiring on the stretchable substrate, in which a loss elastic modulus E″ (S) of the stretchable substrate is smaller than a loss elastic modulus E″ (W) of the stretchable wiring, is provided.

With the stretchable device according to the embodiment of the present disclosure, it is possible to make the stretchable substrate less likely to plastically deform when the stretchable device is stretched.

### BRIEF EXPLANATION OF THE DRAWINGS

FIG. 1 is a sectional view schematically illustrating a stretchable device according to a first embodiment of the present disclosure.

FIG. 2 is a sectional view schematically illustrating a stretchable device according to a second embodiment of the present disclosure.

FIG. 3 is a sectional view schematically illustrating a stretchable device according to a third embodiment of the present disclosure.

### DESCRIPTION OF THE PREFERRED EMBODIMENTS

Hereinafter, embodiments of the present disclosure will be described in detail with reference to the drawings. In each embodiment, differences from the description before the embodiment will be mainly described. Particularly, similar functions and effects achieved by similar configurations will not be mentioned sequentially for each of the embodiments. Among constituent elements in the embodiments below, a constituent element not described in an independent claim will be described as an optional constituent element. Further, sizes and size-ratios of constituent elements illustrated in the drawings are not necessarily precise. Further, in the drawings, substantially the same configurations are denoted by the same reference numerals, and redundant description may be omitted or simplified.

### First Embodiment

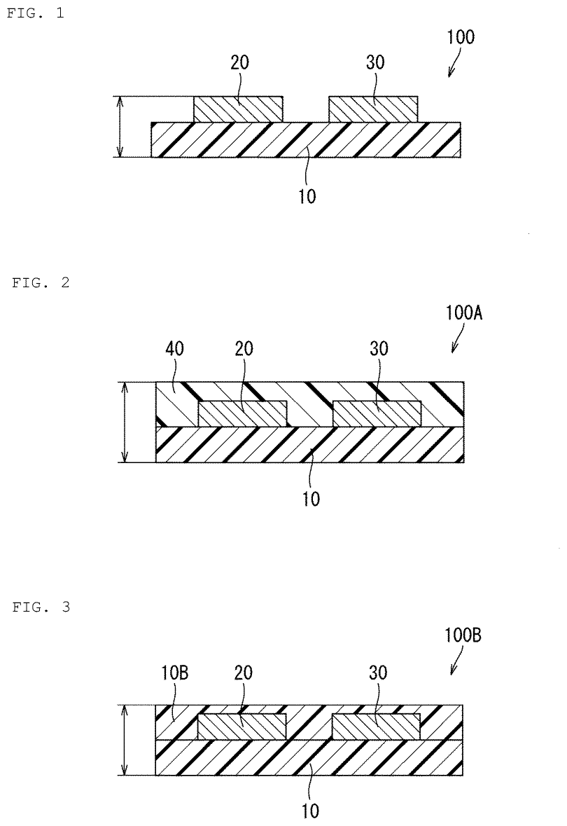

Hereinafter, a configuration of a stretchable device 100 according to a first embodiment of the present disclosure will be described with reference to FIG. 1. FIG. 1 is a sectional view schematically illustrating the stretchable device according to the first embodiment of the present disclosure.

The stretchable device 100 according to the first embodiment of the present disclosure includes a stretchable substrate 10 and at least one stretchable wiring disposed on the stretchable substrate 10. Examples of the at least one stretchable wiring include a first stretchable wiring 20 and a second stretchable wiring 30.

Note that a term “above” in the present specification includes a state of an element being located above a certain element, that is, above a certain element with another object interposed therebetween, a state of an element being located above a certain element at an interval, and a state of an element being located immediately above a certain element in contact with the certain element.

Therefore, in the present specification, “a stretchable wiring disposed above a stretchable substrate” includes a stretchable wiring in a state of being in contact with a main surface of the stretchable substrate, and a stretchable wiring in a state of being separated from the main surface with another member (for example, a resin layer described later) interposed therebetween without being in direct contact with the main surface of the stretchable substrate.

The resin layer may be formed of, for example, at least one resin material selected from the group consisting of a polyimide-based elastomer, an epoxy resin, a urethane-based resin, and an acrylic resin. The resin layer may be formed of an inorganic material such as alumina and silicon dioxide.

The stretchable substrate is a sheet-shaped or film-shaped stretchable substrate, and is composed of, for example, a resin material having stretchability. Examples of the resin material of the stretchable substrate include a styrene-based elastomer, an olefin-based elastomer, a urethane-based elastomer, and a silicone-based elastomer.

A thickness of the stretchable substrate is not particularly limited, but is preferably 100 μm or less, and more preferably is 50 μm or less, from the viewpoint of not inhibiting stretching of a surface of a living body when the device is attached to the living body. In addition, the thickness of the stretchable substrate is preferably 10 μm or more from the viewpoint of securing a predetermined strength.

Each of the stretchable wirings contains conductive particles and resin. Examples of a material of each of the stretchable wirings include a mixture of metal powder of Ag, Cu, Ni, or the like as the conductive particles and a resin material such as acrylic and silicone-based resins. An average particle size of the conductive particles is not particularly limited, but is preferably 0.01 μm to 10 μm. In addition, shapes of the conductive particles are preferably spherical.

A thickness of each of the stretchable wirings is not particularly limited, but is preferably 100 μm or less and more preferably is 50 μm or less. In addition, the thickness of each of the stretchable wirings is preferably 0.01 μm or more. A line width of each of the stretchable wirings is not particularly limited, but is preferably 0.1 μm or more and more preferably is 1 mm or less. A shape and the like of each of the stretchable wirings are not particularly limited.

On the premise of the above configurations, the inventors of the present application have intensively studied a solution for providing a stretchable substrate that is less likely to plastically deform when a stretchable device is stretched. As a result, the inventors of the present application have devised the present disclosure focusing on a viscoelastic characteristic rather than a structure and a shape of each constituent element of the stretchable device.

Specifically, the present disclosure has a feature that in the stretchable device 100, a loss elastic modulus E″ (S) of the stretchable substrate 10 is smaller than loss elastic moduli E″ (W) of the stretchable wirings 20 and 30. The loss elastic modulus as used herein refers to a measure of energy lost from a constituent element due to heat generation or the like during deformation, and refers to a degree of relaxation of the stretchable substrate/the stretchable wiring. A larger value of the loss elastic modulus means that the constituent element is more likely to relax, and a smaller value means that the constituent element is less likely to relax.

According to this feature, since the loss elastic modulus E″ (S) of the stretchable substrate 10 is smaller than the loss elastic moduli E″ (W) of the stretchable wirings 20 and 30, the stretchable substrate is less likely to plastically deform than the stretchable wirings when the stretchable device is stretched. That is, the stretchable substrate can be made less likely to relax than the stretchable wirings when the stretchable device is stretched. This allows the stretchable wirings 20 and 30 arranged on the stretchable substrate 10 to be restrained from gradually extending, which makes it possible to restrain an increase in wiring resistance of the stretchable wirings 20 and 30.

In the above configuration, a ratio of the loss elastic modulus E″ (S) of the stretchable substrate 10 to the loss elastic modulus E″ (W) of each of the stretchable wirings 20 and 30 is smaller than 1 from the viewpoint of making the stretchable substrate less likely to plastically deform than the stretchable wirings.

For example, an upper limit of the above ratio may be, for example, 0.6 or less. From the viewpoint of making the stretchable substrate less likely to plastically deform than the stretchable wirings, the upper limit of the ratio is preferably 0.1 or less, and may be, for example, 0.07, more preferably 0.05 or less, and still more preferably 0.02 or less.

In the present embodiment, a storage elastic modulus E′ (S) of the stretchable substrate 10 is preferably smaller than storage elastic moduli E′ (W) of the stretchable wirings 20 and 30.

The storage elastic modulus as used herein refers to a measure of energy stored in a constituent element during deformation, and refers to a value indicating a degree of stiffness of the stretchable substrate/the stretchable wiring. A larger value of the storage elastic modulus means that the constituent element is relatively stiff, and a smaller value means that the constituent element is flexible.

According to this feature, since a relatively flexible material to the stretchable wirings 20 and 30 may be selected as the stretchable substrate 10, it is possible to hinder the stretchable wirings from extending when the stretchable device 100 is stretched.

In the above configuration, a ratio of the storage elastic modulus E′ (S) of the stretchable substrate 10 to the storage elastic modulus E′ (W) of each of the stretchable wirings 20 and 30 is 0.001 or more from the viewpoint of securing a stretching function of the substrate 10 itself, and from the viewpoint of making the stretchable substrate more flexible than the stretchable wirings, the ratio is smaller than 1.0.

An upper limit of the above ratio is preferably 0.5 or less from the viewpoint of appropriately making the stretchable substrate 10 flexible, and is, for example, 0.2 or less. The upper limit of the above ratio is more preferably 0.1 or less from the viewpoint of more appropriately making the stretchable substrate flexible, and is, for example, 0.06, and further more preferably is 0.05 or less.

A ratio of a loss tangent tanδ(S) of the stretchable substrate 10 to a loss tangent tanδ(W) of each of the stretchable wirings 20 and 30 is 0.01 or more from the viewpoint of securing a viscoelasticity of the stretchable substrate/the stretchable wiring, and is 6.0 or less from the viewpoint of curbing a rate of increase in wiring resistance after repeated stretching to a predetermined value or less.

The loss tangent tanδ as used herein refers to a ratio of the loss elastic modulus E″ of the stretchable wiring or the stretchable substrate to the storage elastic modulus E′ of the stretchable wiring or the stretchable substrate, and indicates which property of an elastic property and a viscous property is strongly exhibited in deformation of a certain viscoelastic body.

In particular, when the ratio of the loss elastic modulus E″ (S) of the stretchable substrate to the loss elastic modulus E″ (W) of the stretchable wiring is 0.1 or less, the ratio of the loss tangent tanδ(S) of the stretchable substrate 10 to the loss tangent tanδ(W) of each of the stretchable wirings 20 and 30 is preferably 1.5 or less from the viewpoint of appropriately curbing the rate of increase in wiring resistance after repeated stretching, more preferably is 1.0 or less, and still more preferably is 0.5 or less.

Furthermore, on the premise that the loss elastic modulus E″ (S) of the stretchable substrate 10 is smaller than the loss elastic modulus E″ (W) of each of the stretchable wirings 20 and 30, the stretchable substrate 10 and the stretchable wirings 20 and 30, when having predetermined values, may have the following feature. Specifically, a ratio of the thickness of each of the stretchable wirings 20 and 30 to a total thickness of the stretchable device 100 is preferably 50% or less.

According to such a feature, it is possible to restrain the increase in wiring resistance that may occur when a proportion of the stretchable wiring in the entire stretchable device 100 is relatively large. From the viewpoint of appropriately restraining such increase in wiring resistance, the ratio of the thickness of the stretchable wiring is more preferably 30% or less, and more preferably is 15% or less. In addition, in the stretchable device 100, the ratio of the thickness of the stretchable wiring is preferably 5% or more from the viewpoint of securing a wiring function.

Furthermore, in terms of a sectional area that may have a correlation with the thickness of the stretchable wiring, a ratio of a sectional area of the stretchable wirings 20 and 30 to a total sectional area of the stretchable device 100 is preferably 50% or less.

According to such a feature, it is possible to restrain the increase in wiring resistance that may occur when the proportion of the stretchable wiring in the entire stretchable device 100 is relatively large. From the viewpoint of appropriately restraining the increase in wiring resistance, the ratio of the sectional area of the stretchable wirings is more preferably 30% or less, and more preferably is 15% or less. In addition, in the stretchable device 100, the ratio of the sectional area of the stretchable wirings is preferably 2% or more from the viewpoint of securing the wiring function.

The stretchable device 100 can be produced through the following steps. Specifically, first, the stretchable substrate 10 is prepared. As the stretchable substrate 10, one having a loss elastic modulus E″ (S) smaller than a loss elastic modulus E″ (W) of each of stretchable wirings to be formed later is selected.

Next, after the stretchable substrate 10 is prepared, a continuous wiring material or separate wiring materials are screen-printed on the prepared stretchable substrate 10, and then dried. In this manner, the stretchable wirings 20 and 30 can be formed on the stretchable substrate 10. As described above, the stretchable device 100 can be produced.

### Second Embodiment

Hereinafter, a second embodiment will be described below. FIG. 2 is a sectional view schematically illustrating a stretchable device according to the second embodiment of the present disclosure. The second embodiment is different from the first embodiment in further including a coating layer 40 that covers a stretchable substrate 10 and stretchable wirings 20 and 30.

In this case as well, the coating layer 40 preferably has a viscoelastic characteristic similar to that of the stretchable substrate 10 from the viewpoint of making the coating layer 40 less likely to plastically deform than the stretchable wirings when the stretchable device is stretched. Specifically, in a stretchable device 100A, a loss elastic modulus E″ (S) of the coating layer 40 is preferably smaller than loss elastic moduli E″ (W) of the stretchable wirings 20 and 30. Note that in the second embodiment, the stretchable substrate 10 and the coating layer 40 may not have the same material composition.

Thus, it is possible to make both the stretchable substrate 10 and the coating layer 40 less likely to plastically deform at substantially the same level than the stretchable wirings when the stretchable device is stretched. As a result, the wiring resistances of the stretchable wirings 20 and 30 can be appropriately restrained from increasing as the entire stretchable device 100A, in spite of presence of the coating layer 40.

### Third Embodiment

Hereinafter, a third embodiment will be described below. The third embodiment is different from the first embodiment in further including a stretchable substrate 10 and a coating layer 10B that covers stretchable wirings 20 and 30.

The coating layer 10B may have the same function as that of the coating layer 40 in the second embodiment. In the third embodiment, the stretchable substrate 10 and the coating layer 10B can have the same material composition. Hence, it is possible to make both the stretchable substrate 10 and the coating layer 10B less likely to plastically deform at substantially the same level than the stretchable wirings when a stretchable device is stretched. As a result, the wiring resistances of the stretchable wirings 20 and 30 can be appropriately restrained from increasing as an entire stretchable device 100B, in spite of presence of the coating layer 10B.

### EXAMPLES

Examples of the present disclosure will be described below.

### Example 1

First, a stretchable substrate 10 was prepared. As the stretchable substrate 10, one having a loss elastic modulus E″ (S) smaller than loss elastic moduli E″ (W) of stretchable wirings to be formed later was selected. Specifically, a styrene-based elastomer was prepared as the stretchable substrate 10.

As the stretchable substrate 10, one having (1) loss elastic modulus E″ (S), (2) storage elastic modulus E′ (S), and (3) loss tangent tanδ(S) (E″ (S)/E′ (S)) indicated in Table 1 was selected.
(1) Loss elastic modulus E″ (S): 15.9 MPa
(2) Storage elastic modulus E′ (S): 19.4 MPa
(3) Loss tangent tanδ(S) (E″ (S)/E′ (S)): 0.90

As a wiring material, a mixed material of Ag particles and an acrylic resin with Ag particles mixed was used. As this wiring material, such a material composition was adopted that after device production, the stretchable wirings each having (1) loss elastic modulus E″ (W), (2) storage elastic modulus E′ (W), and (3) loss tangent tanδ(W) (E″ (W)/E′ (W)) indicated in Table 1 could be obtained.
(1) Loss elastic modulus E″ (W): 28.7 MPa
(2) Storage elastic modulus E′ (W): 162.3 MPa
(3) Loss tangent tanδ(W) (E″ (W)/E′ (W)): 0.18

The wiring material was screen-printed on the prepared stretchable substrate 10, and then dried using a drying device. In this manner, a stretchable device 100 including the stretchable substrate 10 and stretchable wirings 20 and 30 formed on the stretchable substrate was produced (see FIG. 1).

The above-described (1) loss elastic moduli E″, (2) storage elastic moduli E′, and (3) loss tangents tanδ(E″/E′) of the stretchable substrate 10 and the stretchable wirings 20 and 30, were measured using a dynamic viscoelasticity measuring device (RSA-G2 manufactured by TA Instruments). Specifically, the stretchable substrate was vertically shaken and deformed to provide distortion, and the above-described (1) loss elastic moduli E″ and (2) storage elastic moduli E′ each were measured from waveforms of shear stress as responses and a phase difference thereof. From these measured values, (3) loss tangents tanδ(E″/E′) were calculated.

From the above, the ratio of the loss elastic modulus E″ (S) of the stretchable substrate to the loss elastic modulus E″ (W) of the stretchable wiring was 0.56. The ratio of the storage elastic modulus E′ (S) of the stretchable substrate to the storage elastic modulus E′ (W) of the stretchable wiring was 0.12. Further, the ratio of the loss tangent tanδ(S) of the stretchable substrate to the loss tangent tanδ(W) of the stretchable wiring was 5.08.

In Example 1, in the produced stretchable device 100, the thickness of the stretchable wiring was 30 μm, and the total thickness of the stretchable device was 100 μm. Further, in the produced stretchable device 100, the sectional area in the thickness of the stretchable wirings was 30% of the entire sectional area of the stretchable device.

[Measurement of wiring resistance before and after use of device, measurement of rate of increase in wiring resistance, and determination of ability to stretch]

Under the above configuration, the wiring resistance of the stretchable wiring before use (initial state) of the stretchable device 100 was measured by a 4-terminal method. In the present Example, the wiring resistance at this time was set to 100 (index) as a reference. In addition, the wiring resistance of the stretchable wiring was measured after the wiring was extended by 10% and stretched 70 times. The wiring resistance (index) at this time was 150 with respect to 100 of the wiring resistance (index) before use (initial state) of the stretchable device 100. From the above, the rate of increase in wiring resistance was +50%. Furthermore, in Example 1, the stretchable device 100 was able to stretch.

Note that in Examples 2 to 8 described below as well as Example 1, a rate of increase in wiring resistance of +100% or less is treated as Examples, while a rate of increase in wiring resistance of more than +100% is treated as Comparative Examples.

Hereinafter, Example 2 and subsequent Examples will be described focusing on points different from Example 1. Descriptions overlapping with descriptions in Example 1 will be omitted or excluded.

### Example 2

As indicated in Table 1, Example 2 is different from Example 1 in that both of the ratio of the thickness of each stretchable wiring to the total thickness of an obtained stretchable device, and the ratio of the sectional area of the stretchable wirings to the total sectional area of the stretchable device were changed from 30% to 50%. On the other hand, each of the ratio of the loss elastic modulus, the ratio of the storage elastic modulus, and the ratio of the loss tangent between the stretchable wiring and a stretchable substrate was the same as those in Example 1.

Under the above configuration, the wiring resistance (index) after stretching was 200 with respect to 100 of the wiring resistance (index) before use (initial state) of a stretchable device 100. From the above, the rate of increase in wiring resistance was +100%. Note that similarly to Example 1, the stretchable device 100 was able to stretch.

### Example 3

As indicated in Table 1, Example 3 is different from Example 1 in that both of the ratio of the thickness of each stretchable wiring to the total thickness of an obtained stretchable device, and the ratio of the sectional area of the stretchable wirings to the total sectional area of the stretchable device were changed from 30% to 15%. On the other hand, each of the ratio of the loss elastic modulus, the ratio of the storage elastic modulus, and the ratio of the loss tangent between the stretchable wiring and a stretchable substrate was the same as those in Example 1.

Under the above configuration, the wiring resistance (index) after stretching was 135 with respect to 100 of the wiring resistance (index) before use (initial state) of a stretchable device 100. From the above, the rate of increase in wiring resistance was +35%. Note that similarly to Example 1, the stretchable device 100 was able to stretch.

### Example 4

In Example 4, as a stretchable substrate 10, one having (1) loss elastic modulus E″ (S), (2) storage elastic modulus E′ (S), and (3) loss tangent tanδ(S) (E″ (S)/E′ (S)) indicated in Table 1 was selected.
(1) Loss elastic modulus E″ (S): 1.9 MPa
(2) Storage elastic modulus E′ (S): 10.2 MPa
(3) Loss tangent tanδ(S) (E″ (S)/E′ (S)): 0.19

On the other hand, the ratio of the thickness of each stretchable wiring to the total thickness of an obtained stretchable device, and the ratio of the sectional area of the stretchable wirings to the total sectional area of the stretchable device, as well as (1) loss elastic modulus E″ (W), (2) storage elastic modulus E′ (W), and (3) loss tangent tanδ of the stretchable wiring, were the same as those in Example 1.

From the above, the ratio of the loss elastic modulus E″ (S) of the stretchable substrate to the loss elastic modulus E″ (W) of the stretchable wiring was 0.07. The ratio of the storage elastic modulus E′ (S) of the stretchable substrate to the storage elastic modulus E′ (W) of the stretchable wiring was 0.06. Further, the ratio of the loss tangent tanδ(S) of the stretchable substrate to the loss tangent tanδ(W) of the stretchable wiring was 1.06.

Under the above configuration, the wiring resistance (index) after stretching was 135 with respect to 100 of the wiring resistance (index) before use (initial state) of a stretchable device 100. From the above, the rate of increase in wiring resistance was +35%. Note that similarly to Example 1, the stretchable device 100 was able to stretch.

Hereinafter, Example 5 and subsequent Examples will be described focusing on points different from Example 4. Descriptions overlapping with descriptions in Example 4 will be omitted or excluded.

### Example 5

As indicated in Table 1, Example 5 is different from Example 4 in that both of the ratio of the thickness of each stretchable wiring to the total thickness of an obtained stretchable device, and the ratio of the sectional area of the stretchable wirings to the total sectional area of the stretchable device were changed from 30% to 50%. On the other hand, each of the ratio of the loss elastic modulus, the ratio of the storage elastic modulus, and the ratio of the loss tangent between the stretchable wiring and the stretchable substrate were the same as those in Example 4.

Under the above configuration, the wiring resistance (index) after stretching was 160 with respect to 100 of the wiring resistance (index) before use (initial state) of a stretchable device 100. From the above, the rate of increase in wiring resistance was +60%. Note that similarly to Example 1, the stretchable device 100 was able to stretch.

### Example 6

As indicated in Table 1, Example 6 is different from Example 4 in that both of the ratio of the thickness of each stretchable wiring to the total thickness of an obtained stretchable device, and the ratio of the sectional area of the stretchable wirings to the total sectional area of the stretchable device were changed from 30% to 15%. On the other hand, each of the ratio of the loss elastic modulus, the ratio of the storage elastic modulus, and the ratio of the loss tangent between the stretchable wiring and the stretchable substrate were the same as those in Example 4.

Under the above configuration, the wiring resistance (index) after stretching was 120 with respect to 100 of the wiring resistance (index) before use (initial state) of a stretchable device 100. From the above, the rate of increase in wiring resistance was +20%. Note that similarly to Example 1, the stretchable device 100 was able to stretch.

Hereinafter, Example 7 and a subsequent Example will be described focusing on points different from Example 1. Descriptions overlapping with descriptions in Example 1 will be omitted or excluded.

### Example 7

In Example 7, as a stretchable substrate 10, one, different from that of Example 1, having (1) loss elastic modulus E″ (S), (2) storage elastic modulus E′ (S), and (3) loss tangent tanδ(S) (E″ (S)/E′ (S)) indicated in Table 1 was selected.
(1) Loss elastic modulus E″ (S): 1.4 MPa
(2) Storage elastic modulus E′ (S): 10.4 MPa
(3) Loss tangent tanδ(S) (E″ (S)/E′ (S)): 0.14

On the other hand, the ratio of the thickness of each stretchable wiring to the total thickness of an obtained stretchable device, and the ratio of the sectional area of the stretchable wirings to the total sectional area of the stretchable device, as well as (1) loss elastic modulus E″ (W), (2) storage elastic modulus E′ (W), and (3) loss tangent tanδ of the stretchable wiring, were the same as those in Example 1.

From the above, the ratio of the loss elastic modulus E″ (S) of the stretchable substrate to the loss elastic modulus E″ (W) of the stretchable wiring was 0.05. The ratio of the storage elastic modulus E′ (S) of the stretchable substrate to the storage elastic modulus E′ (W) of the stretchable wiring was 0.06. Further, the ratio of the loss tangent tanδ(S) of the stretchable substrate to the loss tangent tanδ(W) of the stretchable wiring was 0.78.

Under the above configuration, the wiring resistance (index) after stretching was 125 with respect to 100 of the wiring resistance (index) before use (initial state) of a stretchable device 100. From the above, the rate of increase in wiring resistance was +25%. Note that similarly to Example 1, the stretchable device 100 was able to stretch.

### Example 8

In Example 8, as a stretchable substrate 10, one, different from that of Example 1, having (1) loss elastic modulus E″ (S), (2) storage elastic modulus E′ (S), and (3) loss tangent tanδ(S) (E″ (S)/E′ (S)) indicated in Table 1 was selected.
(1) Loss elastic modulus E″ (S): 0.6 MPa
(2) Storage elastic modulus E′ (S): 7.8 MPa
(3) Loss tangent tanδ(S) (E″ (S)/E′ (S)): 0.08

On the other hand, the ratio of the thickness of each stretchable wiring to the total thickness of an obtained stretchable device, and the ratio of the sectional area of the stretchable wirings to the total sectional area of the stretchable device, as well as (1) loss elastic modulus E″ (W), (2) storage elastic modulus E′ (W), and (3) loss tangent tanδ of the stretchable wiring, were the same as those in Example 1.

From the above, the ratio of the loss elastic modulus E″ (S) of the stretchable substrate to the loss elastic modulus E″ (W) of the stretchable wiring was 0.02. The ratio of the storage elastic modulus E′ (S) of the stretchable substrate to the storage elastic modulus E′ (W) of the stretchable wiring was 0.05. The ratio of the loss tangent tanδ(S) of the stretchable substrate to the loss tangent tanδ(W) of the stretchable wiring was 0.45.

Under the above configuration, the wiring resistance (index) after stretching was 120 with respect to 100 of the wiring resistance (index) before use (initial state) of a stretchable device 100. From the above, the rate of increase in wiring resistance was +20%. Note that similarly to Example 1, the stretchable device 100 was able to stretch.

### Comparative Example 1

In Comparative Example 1, as a stretchable substrate, one, different from that of Example 1, having (1) loss elastic modulus E″ (S), (2) storage elastic modulus E′ (S), and (3) loss tangent tanδ(S) (E″ (S)/E′ (S)) indicated in Table 1 was selected.
(1) Loss elastic modulus E″ (S): 43.6 MPa
(2) Storage elastic modulus E′ (S): 147.2 MPa
(3) Loss tangent tanδ(S) (E″ (S)/E′ (S)): 0.30

On the other hand, the ratio of the thickness of each stretchable wiring to the total thickness of an obtained stretchable device, and the ratio of the sectional area of the stretchable wirings to the total sectional area of the stretchable device, as well as (1) loss elastic modulus E″ (W), (2) storage elastic modulus E′ (W), and (3) loss tangent tanδ of the stretchable wiring, were the same as those in Example 1.

From the above, the ratio of the loss elastic modulus E″ (S) of the stretchable substrate to the loss elastic modulus E″ (W) of the stretchable wiring was 1.52. The ratio of the storage elastic modulus E′ (S) of the stretchable substrate to the storage elastic modulus E′ (W) of the stretchable wiring was 0.91. The ratio of the loss tangent tanδ(S) of the stretchable substrate to the loss tangent tanδ(W) of the stretchable wiring was 1.68.

Under the above configuration, the wiring resistance (index) after stretching was 220 with respect to 100 of the wiring resistance (index) before use (initial state) of a stretchable device. From the above, the rate of increase in wiring resistance was +120%. Note that similarly to Example 1, the stretchable device was able to stretch.

### Comparative Example 2

In Comparative Example 2, as a stretchable substrate, one, different from that of Example 1, having (1) loss elastic modulus E″ (S), (2) storage elastic modulus

E′ (S), and (3) loss tangent tanδ(S) (E″ (S)/E′ (S)) indicated in Table 1 was selected.
(1) Loss elastic modulus E″ (S): 69.9 MPa
(2) Storage elastic modulus E′ (S): 659.5 MPa
(3) Loss tangent tanδ(S) (E″ (S)/E′ (S)): 0.11

On the other hand, the ratio of the thickness of each stretchable wiring to the total thickness of an obtained stretchable device, and the ratio of the sectional area of the stretchable wirings to the total sectional area of the stretchable device, as well as (1) loss elastic modulus E″ (W), (2) storage elastic modulus E′ (W), and (3) loss tangent tanδ of the stretchable wiring, were the same as those in Example 1.

From the above, the ratio of the loss elastic modulus E″ (S) of the stretchable substrate to the loss elastic modulus E″ (W) of the stretchable wiring was 2.4. The ratio of the storage elastic modulus E′ (S) of the stretchable substrate to the storage elastic modulus E′ (W) of the stretchable wiring was 4.1. The ratio of the loss tangent tanδ(S) of the stretchable substrate to the loss tangent tanδ(W) of the stretchable wiring was 0.6.

Under the above configuration, in Comparative Example 2, since the storage elastic modulus E′ (S) of the stretchable substrate was about 35 times with respect to that in Example 1, the stretchable substrate was relatively stiff and was not able to stretch. As a result, stretching of the stretchable device was impossible.

### Comparative Example 3

In Comparative Example 3, as a stretchable substrate, one, different from that of Example 1, having (1) loss elastic modulus E″ (S), (2) storage elastic modulus E′ (S), and (3) loss tangent tanδ(S) (E″ (S)/E′ (S)) indicated in Table 1 was selected.
(1) Loss elastic modulus E″ (S): 272.4 MPa
(2) Storage elastic modulus E′ (S): 3728.5 MPa
(3) Loss tangent tanδ(S) (E″ (S)/E′ (S)): 0.07

On the other hand, the ratio of the thickness of each stretchable wiring to the total thickness of an obtained stretchable device, and the ratio of the sectional area of the stretchable wirings to the total sectional area of the stretchable device, as well as (1) loss elastic modulus E″ (W), (2) storage elastic modulus E′ (W), and (3) loss tangent tanδ of the stretchable wiring, were the same as those in Example 1.

From the above, the ratio of the loss elastic modulus E″ (S) of the stretchable substrate to the loss elastic modulus E″ (W) of the stretchable wiring was 9.5. The ratio of the storage elastic modulus E′ (S) of the stretchable substrate to the storage elastic modulus E′ (W) of the stretchable wiring was 23.0. The ratio of the loss tangent tanδ(S) of the stretchable substrate to the loss tangent tanδ(W) of the stretchable wiring was 0.4.

Under the above configuration, in Comparative Example 3, since the storage elastic modulus E′ (S) of the stretchable substrate was about 190 times with respect to that in Example 1, the stretchable substrate was relatively stiff and was not able to stretch. As a result, stretching of the stretchable device was impossible.

TABLE 1

| | Example 1 | Example 2 | Example 3 | Example 4 | Example 5 | Example 6 |
|---|---|---|---|---|---|---|
| Loss elastic modulus E″(W) | 28.7 | 28.7 | 28.7 | 28.7 | 28.7 | 28.7 |
| Mpa | | | | | | |
| Storage elastic modulus E′(W) | 162.3 | 162.3 | 162.3 | 162.3 | 162.3 | 162.3 |
| Mpa | | | | | | |
| Loss tangent tanδ(W) | 0.18 | 0.18 | 0.18 | 0.18 | 0.18 | 0.18 |
| (E″(W)/E′(W)) | | | | | | |
| Loss elastic modulus E″(S) | 15.9 | 15.9 | 15.9 | 1.9 | 1.9 | 1.9 |
| Mpa | | | | | | |
| Storage elastic modulus E′(S) | 19.4 | 19.4 | 19.4 | 10.2 | 10.2 | 10.2 |
| Mpa | | | | | | |
| Loss tangent tanδ(S) | 0.9 | 0.9 | 0.9 | 0.19 | 0.19 | 0.19 |
| (E″(S)/E′(S)) | | | | | | |
| Ratio of loss elastic modulus | 0.56 | 0.56 | 0.56 | 0.07 | 0.07 | 0.07 |
| E″ (E″(S)/E″(W)) | | | | | | |
| Ratio of storage elastic | 0.12 | 0.12 | 0.12 | 0.06 | 0.06 | 0.06 |
| modulus E′ (E′(S)/E′(W)) | | | | | | |
| Ratio of loss tangent tanδ | 5.08 | 5.08 | 5.08 | 1.06 | 1.06 | 1.06 |
| (tanδ(S)/tanδ(W)) | | | | | | |
| Ratio (%) of thickness of | 30 | 50 | 15 | 30 | 50 | 15 |
| stretchable wiring to total | | | | | | |
| thickness of stretchable | | | | | | |
| device | | | | | | |
| Ratio (%) of sectional area of | 30 | 50 | 15 | 30 | 50 | 15 |
| stretchable wirings to total | | | | | | |
| sectional area of stretchable | | | | | | |
| device | | | | | | |
| Wiring resistance | 100 | 100 | 100 | 100 | 100 | 100 |
| (index)(initial state = 100) | | | | | | |
| Wiring resistance (index)(10% | 150 | 200 | 135 | 135 | 160 | 120 |
| after stretching 70 times) | | | | | | |
| Rate of increase in wiring | 50 | 100 | 35 | 35 | 60 | 20 |
| resistance (%)(after | | | | | | |
| stretching − initial state) | | | | | | |
| Stretchable | Yes | Yes | Yes | Yes | Yes | Yes |

| | | | Comparative | Comparative | Comparative |
|---|---|---|---|---|---|
| | Example 7 | Example 8 | Example 1 | Example 2 | Example 3 |
| Loss elastic modulus E″(W) | 28.7 | 28.7 | 28.7 | 28.7 | 28.7 |
| Mpa | | | | | |
| Storage elastic modulus E′(W) | 162.3 | 162.3 | 162.3 | 162.3 | 162.3 |
| Mpa | | | | | |
| Loss tangent tanδ(W) | 0.18 | 0.18 | 0.18 | 0.18 | 0.18 |
| (E″(W)/E′(W)) | | | | | |
| Loss elastic modulus E″(S) | 1.4 | 0.6 | 43.6 | 69.9 | 272.4 |
| Mpa | | | | | |
| Storage elastic modulus E′(S) | 10.4 | 7.8 | 147.2 | 659.5 | 3728.5 |
| Mpa | | | | | |
| Loss tangent tanδ(S) | 0.14 | 0.08 | 0.3 | 0.11 | 0.07 |
| (E″(S)/E′(S)) | | | | | |
| Ratio of loss elastic modulus | 0.05 | 0.02 | 1.52 | 2.40 | 9.50 |
| E″ (E″(S)/E″(W)) | | | | | |
| Ratio of storage elastic | 0.06 | 0.05 | 0.91 | 4.1 | 23 |
| modulus E′ (E′(S)/E′(W)) | | | | | |
| Ratio of loss tangent tanδ | 0.78 | 0.45 | 1.68 | 0.6 | 0.4 |
| (tanδ(S)/tanδ(W)) | | | | | |
| Ratio (%) of thickness of | 30 | 30 | 30 | 30 | 30 |
| stretchable wiring to total | | | | | |
| thickness of stretchable | | | | | |
| device | | | | | |
| Ratio (%) of sectional area of | 30 | 30 | 30 | 30 | 30 |
| stretchable wirings to total | | | | | |
| sectional area of stretchable | | | | | |
| device | | | | | |
| Wiring resistance | 100 | 100 | 100 | — | — |
| (index)(initial state = 100) | | | | | |
| Wiring resistance (index)(10% | 125 | 120 | 220 | — | — |
| after stretching 70 times) | | | | | |
| Rate of increase in wiring | 25 | 20 | 120 | — | — |
| resistance (%)(after | | | | | |
| stretching − initial state) | | | | | |
| Stretchable | Yes | Yes | Yes | No | No |

From the above, comparing Examples 1 to 8 with Comparative Example 1, it was found that in the stretchable device 100, when the loss elastic modulus E″ (S) of the stretchable substrate 10 is smaller than the loss elastic modulus E″ (W) of each of the stretchable wirings 20 and 30, the rate of increase in wiring resistance is +100% or less.

Specifically, it was found that when the ratio of the loss elastic modulus E″ (S) of the stretchable substrate 10 to the loss elastic modulus E″ (W) of each of the stretchable wirings 20 and 30 is smaller than 1, the rate of increase in wiring resistance is +100% or less.

This is understood to be attributed to the fact that when the stretchable device is stretched, the stretchable substrate is less likely to plastically deform than the stretchable wiring, that is, the stretchable substrate is less likely to relax than the stretchable wirings. From the viewpoint of securing toughness of the stretchable substrate 10 itself, it is understood that the above ratio is preferably 0.001 or more.

On the other hand, as indicated in Comparative Examples 1 to 3, it was found that, as compared with Examples 1 to 8, in the stretchable device, when the loss elastic modulus E″ (S) of the stretchable substrate is larger than the loss elastic modulus E″ (W) of the stretchable wiring, the rate of increase in wiring resistance is +120%. In addition, as indicated in Comparative Examples 2 and 3, it was found that since the storage elastic modulus E′ (S) of the stretchable substrate was considerably larger (about 35 times or more) than that in Example, stretching itself was unfeasible.

Moreover, it has been found that when the storage elastic modulus E′ (S) of the stretchable substrate 10 is smaller than the storage elastic modulus E′ (W) of each of the stretchable wirings 20 and 30, specifically, when the ratio of the storage elastic modulus E′ (S) of the stretchable substrate 10 to the storage elastic modulus E′ (W) of each of the stretchable wirings 20 and 30 is smaller than 1.0, the rate of increase in wiring resistance is +100% or less. This is understood to be attributed to the fact that the stretchable substrate is more flexible than the stretchable wirings when the stretchable device is stretched.

In addition, it was found that when the ratio of the loss elastic modulus E″ (S) of the stretchable substrate to the loss elastic modulus E″ (W) of the stretchable wiring is 0.1 or less with a ratio of the loss tangent tanδ(S) of the stretchable substrate 10 to the loss tangent tanδ(W) of each of the stretchable wirings 20 and 30 of 1.5 or less (see Examples 4 to 8), the rate of increase in wiring resistance after repeated stretching can be appropriately curbed as compared with Examples 1 to 3. Moreover, it was found that when that ratio is 1.0 or less (see Examples 7 and 8), the rate of increase in wiring resistance after repeated stretching can be more appropriately curbed as compared with Examples 4 to 6. Furthermore, it was found that when that ratio is 0.5 or less (see Example 8), the rate of increase in wiring resistance after repeated stretching can be more appropriately curbed as compared with Examples 4 to 7.

It was further found that in Example 2, the ratio of the thickness/sectional area of the stretchable wirings 20 and 30 to the total thickness/total sectional area of the stretchable device 100 is 50%, and the rate of increase in wiring resistance is +100%, whereas in Example 1, the ratio is 30%, and the rate of increase in wiring resistance is +50%. It was found that in Example 3, the ratio is 15%, and the rate of increase in wiring resistance is +35%.

From the above, it was found that when the proportion of the stretchable wirings in the entire stretchable device 100 in terms of the thickness or the sectional area, is set to a predetermined value or less (50% or less), a rate of increase in wiring resistance of +100% or less can be achieved, unlike Comparative Example 1.

Similarly, it was found that in Example 5, the ratio of the thickness/sectional area of the stretchable wirings 20 and 30 to the total thickness/total sectional area of the stretchable device 100 is 50%, and the rate of increase in wiring resistance is +60%, whereas in Example 4, the ratio is 30%, and the rate of increase in wiring resistance is +35%. It was found that in Example 6, the ratio is 15%, and the rate of increase in wiring resistance is +20%.

From the above, it was additionally found that when the proportion of the stretchable wirings in the entire stretchable device 100 in terms of the thickness or the sectional area, is set to a predetermined value or less (50% or less), a rate of increase in wiring resistance of +100% or less can be achieved, unlike Comparative Example 1.

Note that each of the embodiments and modifications is an example, and the present disclosure is not limited to each of the embodiments and the modifications. In addition, each of the drawings is an example of the constituent elements, and does not limit a shape. Further, partial replacement or combination of the configurations illustrated in different embodiments and modifications is possible.

The stretchable device according to an embodiment of the present disclosure may adopt the following aspects.
<1>A stretchable device including: a stretchable substrate; and a stretchable wiring on the stretchable substrate, in which a loss elastic modulus E″ (S) of the stretchable substrate is smaller than a loss elastic modulus E″ (W) of the stretchable wiring.
<2> The stretchable device according to <1>, in which a ratio of the loss elastic modulus E″ (S) of the stretchable substrate to the loss elastic modulus E″ (W) of the stretchable wiring is 0.001 or more and smaller than 1.
<3> The stretchable device according to <1> or <2>, in which a storage elastic modulus E′ (S) of the stretchable substrate is smaller than a storage elastic modulus E′ (W) of the stretchable wiring.
<4> The stretchable device according to <3>, in which a ratio of the storage elastic modulus E′ (S) of the stretchable substrate to the storage elastic modulus E′ (W) of the stretchable wiring is 0.001 or more and smaller than 1.
<5> The stretchable device according to any of <2> to <4>, in which when the ratio of the loss elastic modulus E″ (S) of the stretchable substrate to the loss elastic modulus E″ (W) of the stretchable wiring is 0.1 or less, a ratio of a loss tangent tanδ(S) of the stretchable substrate to a loss tangent tanδ(W) of the stretchable wiring is 0.01 to 1.5.
<6> The stretchable device according to any of <1> to <5>, in which a ratio (%) of a thickness of the stretchable wiring to a total thickness of the stretchable device is 50% or less.
<7> The stretchable device according to any of <1> to <6>, in which a ratio (%) of a sectional area of the stretchable wiring to a total sectional area of the stretchable device is 50% or less.

### REFERENCE NUMBERS

100, 100A, 100B: Stretchable device
10: Stretchable substrate
20: First stretchable wiring
30: Second stretchable wiring
40: Coating layer
10B: Coating layer

1. A stretchable device comprising:
a stretchable substrate; and
a stretchable wiring on the stretchable substrate, wherein
a loss elastic modulus E″ (S) of the stretchable substrate is smaller than a loss elastic modulus E″ (W) of the stretchable wiring.

2. The stretchable device according to claim 1, wherein a ratio of the loss elastic modulus E″ (S) of the stretchable substrate to the loss elastic modulus E″ (W) of the stretchable wiring is 0.001 or more and smaller than 1.

3. The stretchable device according to claim 2, wherein a storage elastic modulus E′ (S) of the stretchable substrate is smaller than a storage elastic modulus E′ (W) of the stretchable wiring.

4. The stretchable device according to claim 3, wherein a ratio of the storage elastic modulus E′ (S) of the stretchable substrate to the storage elastic modulus E′ (W) of the stretchable wiring is 0.001 or more and smaller than 1.0.

5. The stretchable device according to claim 1, wherein a storage elastic modulus E′ (S) of the stretchable substrate is smaller than a storage elastic modulus E′ (W) of the stretchable wiring.

6. The stretchable device according to claim 5, wherein a ratio of the storage elastic modulus E′ (S) of the stretchable substrate to the storage elastic modulus E′ (W) of the stretchable wiring is 0.001 or more and smaller than 1.0.

7. The stretchable device according to claim 2, wherein when the ratio of the loss elastic modulus E″ (S) of the stretchable substrate to the loss elastic modulus E″ (W) of the stretchable wiring is 0.001 to 0.1, and a ratio of a loss tangent tanδ(S) of the stretchable substrate to a loss tangent tanδ(W) of the stretchable wiring is 0.01 to 1.5.

8. The stretchable device according to claim 1, wherein a ratio of a loss tangent tanδ(S) of the stretchable substrate to a loss tangent tanδ(W) of the stretchable wiring is 0.01 to 6.0.

9. The stretchable device according to claim 1, wherein a ratio (%) of a thickness of the stretchable wiring to a total thickness of the stretchable device is 50% or less.

10. The stretchable device according to claim 1, wherein a ratio (%) of a sectional area of the stretchable wiring to a total sectional area of the stretchable device is 50% or less.

11. The stretchable device according to claim 1, further comprising a coating layer covering the stretchable substrate and the stretchable wiring.

12. The stretchable device according to claim 11, wherein a loss elastic modulus E″ (S) of the coating layer is smaller than the loss elastic modulus E″ (W) of the stretchable wiring.

13. The stretchable device according to claim 11, wherein the stretchable substrate and the coating layer have a same material composition.
